(19) United States
(12) Patent Application Publication
(10) Pub. No.: US 2010/0140274 A1
(43) Pub. Date: Jun. 10, 2010

(54) FIELD HOUSING

(75) Inventors: Wolfgang Lasarzik, Bad Nenndorf (DE); Werner Thoenebe, Barsinghausen (DE); Karsten Thiemeier, Barsinghausen (DE)

Correspondence Address: BUCHANAN, INGERSOLL & ROONEY PC, POST OFFICE BOX 1404, ALEXANDRIA, VA, 22313-1404, US

(73) Assignee: ABB TECHNOLOGY AG, Zurich (CH)

(21) Appl. No.: 12/629,417

(22) Filed: Dec. 2, 2009

(30) Foreign Application Priority Data
Dec. 3, 2008 (DE) 20 2008 016 063.4

(51) Int. Cl. H05K 5/00

(52) U.S. Cl. 220/560.01

(57) ABSTRACT

The disclosure relates to a field housing for enclosing electrical equipment in installations where there is an explosion hazard. To avoid ignition sparks passing between the inside and the outside of the field housing, the field housing can include a housing cup of a cuboidal shape with a rectangle opening with rounded corners which can be closed with a housing cover. A periphery of the opening can be widened into a surrounding sleeve, and the housing cover can include a peripheral collar of a form and size matching the opening in the housing cup such that a flameproof joint is formed between the collar of the housing cover and the sleeve of the housing cup.

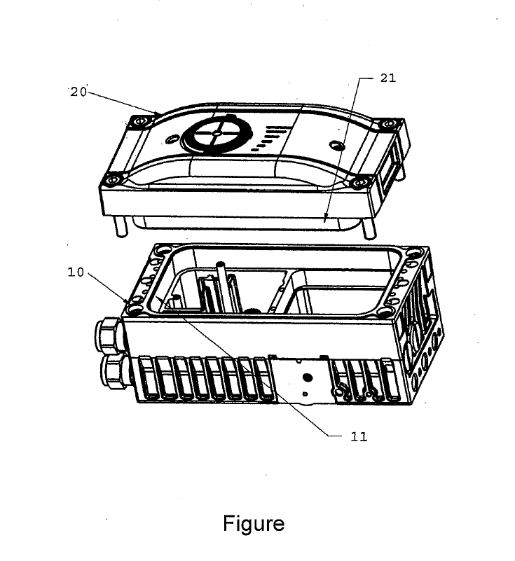

### RELATED APPLICATION

This application claims priority under 35 U.S.C. §119 to German Patent Application No. 20 2008 016 063.4 filed in Germany on Dec. 3, 2008, the entire content of which is hereby incorporated by reference in its entirety.

### FIELD

The disclosure relates to a field housing for enclosing electrical equipment in installations where there is an explosion hazard.

### BACKGROUND INFORMATION

For installations where there is an explosion hazard, electrical devices have to meet special requirements to rule out potential risk of accidents caused by explosion. These requirements are subsumed under so-called types of protection.

When electrotechnical devices and equipment are being installed and put into operation as well as when maintenance work is being carried out on electrotechnical devices and equipment in process engineering installations that are in a potentially explosive atmosphere, it is mandatory to observe the relevant statutory regulations such as the German order on electrical installations in potentially explosive areas ElexV, which is based on the European standards for explosion protection EN 50 014 et seq.

According to the provisions of EN 50 018 and comparable national regulations, electrical equipment that warms up significantly or gives off sparks during its intended use must be enclosed in housings which conform to the flameproof enclosure type of protection whenever the equipment is intended to be used in installations where there is an explosion hazard.

A characteristic of this type of protection is a “flameproof” joint between housing parts, which is specifically configured in terms of its width and length such that an explosion inside is reliably prevented from crossing over to the outside, to a surrounding (i.e., exterior) explosive atmosphere for a given application. The width of the joint refers to a distance between opposing surfaces of the housing parts that remain after the assembly thereof. The length of the flameproof joint is the shortest path through the joint from the inside of the housing to the outside of the housing.

Housings which are closed by a screw-on cover have proven to be successful in practice. In this case, a long gap of a small width is created over a short distance and can be produced at low cost in a simple way. This form of housing can entail a more or less rotationally symmetrical geometry, leading to a larger volume of the housing, since the internal components can have a cuboidal basic shape. Larger volumes, however, can entail greater length/width ratios of the flameproof joint.

### SUMMARY

A field housing is disclosed comprising: a housing cup having a cuboidal shape and a rectangular opening with rounded corners, a periphery of the opening being widened into a surrounding sleeve; and a housing cover which is configured to close the housing cup to form a flameproof joint, wherein the housing cover has a peripheral collar of a form and size matching the opening in the housing cup such that the flameproof joint is formed between the collar of the housing cover and the sleeve of the housing cup.

### BRIEF DESCRIPTION OF THE DRAWINGS

The disclosure is explained in more detail on the basis of an exemplary embodiment as illustrated in the drawing.

The single FIGURE shows in a perspective representation an exemplary two-part field housing.

### DETAILED DESCRIPTION

A field housing is disclosed for enclosing electrical equipment that has a cuboidal shape and can be closed with a cover to form a flameproof joint.

A housing cup can be closed with a housing cover to form the flameproof joint.

According to an exemplary embodiment, the housing cup has a cuboidal shape and a rectangular opening with rounded corners, the periphery of which is widened into a surrounding sleeve. The housing cover has a peripheral collar of a form and size matching the opening in the housing cup in such a way that the flameproof joint is formed between the collar of the housing cover and the sleeve of the housing cup.

When the housing cup is closed with its housing cover, the collar of the housing cover enters the sleeve of the housing cup and is enclosed by the latter to form the flameproof joint.

A field housing according to the disclosure can allow the installation of rectangular or cuboidal electrical components, which are in particular assembled on printed circuit boards, with a small housing volume.

According to a further feature of the disclosure, the sleeve and the collar can have a common depth at which a joint in a corner that lies diametrically opposite a point of contact between the sleeve and the collar is flameproof.

According to a further feature of the disclosure, exemplary radii of the housing cover have only negative tolerances and the radii of the housing cup have only positive tolerances.

Referring to the FIGURE, a two-art field housing includes a housing cup 10 and a housing cover 20. The housing cup 10 has a cuboidal shape and a rectangular opening with rounded corners, the periphery of which is widened into a surrounding sleeve 11. As referenced herein, a cuboidal shape is a shape which is, or which approximates a cube; a rectangular opening is an opening of approximate, or substantial, rectangual shape. The housing cover 20 has a peripheral collar 21 of a form and size matching the opening in the housing cup 10 in such a way that the flameproof joint is formed between the collar 21 of the housing cover 20 and the sleeve 11 of the housing cup 10.

When the housing cup 10 is closed with its housing cover 20, the collar 21 of the housing cover 20 enters the sleeve 11 of the housing cup 10 and is enclosed by the latter to form a flameproof joint.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF DESIGNATIONS

10 housing cup
11 sleeve
20 housing cover
21 collar

What is claimed is:

1. A field housing comprising:
a housing cup having a cuboidal shape and a rectangular opening with rounded corners, a periphery of the opening being widened into a surrounding sleeve; and
a housing cover which is configured to close the housing cup to form a flameproof joint, wherein the housing cover has a peripheral collar of a form and size matching the opening in the housing cup such that the flameproof joint is formed between the collar of the housing cover and the sleeve of the housing cup.

2. The field housing as claimed in claim 1, wherein the sleeve and the collar have a common depth at which a joint in a corner that lies diametrically opposite a point of contact between the sleeve and the collar is flameproof.

3. The field housing as claimed in claim 1, wherein radii of the housing cover have only negative tolerances and radii of the housing cup have only positive tolerances.

4. The field housing as claimed in claim 2, wherein radii of the housing cover have only negative tolerances and radii of the housing cup have only positive tolerances.

5. The field housing as claimed in claim 1, wherein the flameproof joint is configured to prevent an explosion within the field housing from exiting to an exterior atmosphere.
